(19) United States
(12) Patent Application Publication
(10) Pub. No.: US 2024/0094273 A1
(43) Pub. Date: Mar. 21, 2024

(54) WIDEBAND VARIABLE IMPEDANCE LOAD FOR HIGH VOLUME MANUFACTURING QUALIFICATION AND ON-SITE DIAGNOSTICS

(71) Applicant: Applied Materials, Inc., Santa Clara, CA (US)

(72) Inventors: Yue GUO, Redwood City, CA (US); Kartik RAMASWAMY, San Jose, CA (US); Jie YU, Santa Clara, CA (US); Yang YANG, San Diego, CA (US)

(21) Appl. No.: 17/947,675

(22) Filed: Sep. 19, 2022

(51) Int. Cl. G01R 29/08; H01J 37/32

(52) U.S. Cl. CPC G01R 29/0871; H01J 37/32183; H01J 37/32917; H01J 2237/24592

(57) ABSTRACT

A wideband variable impedance load for high volume manufacturing qualification and diagnostic testing of a radio frequency power source, an impedance matching network and RF sensors for generating plasma in a semiconductor plasma chamber for semiconductor fabrication processes. The wideband variable impedance load may comprise a fixed value resistance operable at a plurality of frequencies and coupled with a variable impedance network capable of transforming the fixed value resistance into a wide range of complex impedances at the plurality of frequencies. Response times and match tuning element position repeatability may be verified. Automatic testing, verification and qualification of production and field installed radio frequency power sources for plasma generation are easily performed.

### BACKGROUND

### Field

Embodiments of the present disclosure generally relate to testing of high-power radio frequency (RF) power sources and impedance matching networks, and, in particular, to manufacturing qualification and diagnostic testing of an RF power source and impedance matching network adapted for generating a plasma in chamber.

### Description of the Related Art

Reliably forming high aspect ratio features is one of the key technology challenges for manufacturing the next generation of semiconductor devices. High aspect ratio openings used to form the features are typically formed using a plasma-assisted etch process, such as a reactive ion etch (RIE) process capable of directionally controlled (i.e., anisotropic) material removal to transfer a pattern from a mask layer to exposed portions of the substrate surface there beneath. For plasma etching and other plasma utilizing processes, process uniformity and repeatability within a chamber, from chamber to chamber and processing system to processing system are important parameters for controlling semiconductor device yield and semiconductor device performance tolerance so that the formed semiconductor devices are able to perform as desired.

In plasma reactors, a radio frequency (RF) power source provides RF power to the plasma reactor chamber, for generating plasma therein, via an impedance matching network coupled between the RF power source and the plasma reactor chamber. The RF impedance of a plasma is a complex and highly variable function of many process parameters and conditions. The impedance matching network maximizes power transfer from the RF power source to the plasma in the reactor chamber. This is accomplished when the output impedance of the impedance matching network is equal to the complex conjugate of the input impedance of the plasma in the reactor chamber. The impedance matching network transforms the impedance of the plasma in the reactor chamber to the characteristic operating output impedance of the RF power source, e.g., 50 ohms, for optimal RF power transfer therefrom.

The RF impedance matching network is an electrical circuit disposed between the RF power source and the plasma reactor to optimize RF power transfer efficiency. In high-volume manufacturing, a qualification process is required to validate that the product will meet a design specification. A complex dummy load test is typically implemented to verify if the RF impedance matching network can tune at a desired frequency to a desired complex impedance accurately.

Multiple RF power sources at different frequencies may sometimes be utilized with plasma reactors. This includes multiple RF power sources each having an associated frequency dependent matching network. The frequency dependent matching networks may be connected to the plasma chamber at a common output point. Band pass filters may be included between each frequency dependent matching network and the plasma chamber to provide isolation for the different RF power sources.

Accurate characterization of an impedance matching network is critically important for providing reliable, efficient, and predictable plasma processes. Typically, characterization of an impedance matching network is performed with a dummy load having a complex impedance that may be coupled to the output of the impedance matching network in place of the plasma chamber.

A traditional complex impedance dummy load is thus used for such verification purposes. However, the traditional complex impedance dummy load is typically designed for only a specific impedance at a single frequency and multiple complex impedance dummy loads are required if a multipoint test is required. Also, these tests may require labor-intensive processes because an appropriate complex impedance dummy load is required to be installed manually for every RF matching network under test. In addition, an extra vector network analyzer test is sometimes needed to test RF filters, which may require technical expertise for equipment calibration and operation.

Hence, there is a need for a wideband variable impedance load operable over a plurality of frequencies for high volume manufacturing qualification and diagnostics of RF power sources and associated impedance matching networks used in plasma processes for deposition and/or etching used in the formation of, for example but is not limited to, semiconductor integrated circuits, display panels and solar panels.

### SUMMARY

Embodiments of the disclosure include a wideband radio frequency (RF) variable impedance test load adapted for coupling to an RF power source used to generate a plasma in a plasma processing chamber. The RF variable impedance test load comprises a variable impedance network having a first node that may be adapted for coupling to a resistance, adjustable tuning elements for transforming the resistance coupled to the first node into a plurality of impedances at a second node, wherein the second node may be configured to be coupled to an RF power source. A test unit controller coupled to the adjustable tuning elements such that the test unit controller controls adjustment of the adjustable tuning elements for selected ones of the plurality of impedances at the second node.

Embodiments of the disclosure include a system for analyzing, qualifying or testing a radio frequency (RF) power source and impedance matching network used to generate a plasma in a plasma processing chamber with an RF variable impedance test load. The radio frequency (RF) power source including an RF generator and an impedance matching networking having an input coupled to an output of the RF generator. The wideband RF variable impedance test load includes a variable impedance network having a first node that may be adapted for coupling to a resistance, adjustable tuning elements for transforming the resistance coupled to the first node into a plurality of impedances at a second node, wherein the second node may be configured to be coupled to the output of the impedance matching networking. A test unit controller may be coupled to the adjustable tuning elements such that the controller controls adjustment of the adjustable tuning elements for selected ones of the plurality of impedances at the second node.

Embodiments of the disclosure include a method for analyzing, qualifying or testing, with a radio frequency (RF) variable impedance test load, an RF impedance matching network and components thereof used for generating a plasma in a plasma processing chamber. A resistance may be coupled to a first node of a variable impedance that transforms the resistance into a plurality of load impedances at a second node of the variable impedance network by adjusting tuning elements of the variable impedance network with a controller. The second node may be monitored by RF voltage and current sensors, and a frequency detector whose values may be used to determine impedances of the plurality of load impedances. RF power may be generated at a frequency with an RF generator having an output at a first impedance. An impedance matching network may be coupled between the output of the RF generator and the second node of the variable impedance network. The impedance of the RF generator may be matched to the plurality of load impedances at the second node of the variable impedance network with the impedance matching network.

Embodiments of the disclosure include a method for analyzing, qualifying or testing, with a radio frequency (RF) variable impedance test load, an RF impedance matching network and components thereof used for generating a plasma in a plasma processing chamber. An RF generator delivers a first RF signal through the RF impedance matching network to a first node of the variable impedance network that includes a controller, a second node that is adapted for coupling to a resistance element, adjustable tuning elements for transforming the resistance of the resistance element coupled to the second node into a plurality of load impedances at the first node, and an RF voltage sensor, an RF current sensor and a frequency detector that may be coupled between the first node and the adjustable tuning elements. Matching a first impedance of the RF generator to one of the plurality of load impedances created at the first node of the variable impedance network, where the one of the plurality of load impedances is created by adjusting one or more of the adjustable tuning elements of the impedance matching network. Comparing a signal generated by at least one of the RF voltage sensor, RF current sensor and frequency detector, while the first impedance of the RF generator is matched to the one of the plurality of load impedances, to at least one of RF voltage sensor data, RF current sensor data and frequency detector data stored in memory. Qualifying the impedance matching network if the signal from the RF voltage sensor, RF current sensor and frequency sensor are within a range set relative to the respective at least one of RF voltage sensor data, RF current sensor data and frequency detector data stored in memory.

Embodiments of the disclosure include a system for analyzing, qualifying or testing radio frequency (RF) components, comprising a variable impedance network. The variable impedance network includes a first node that is adapted for coupling to a first resistance element; and adjustable tuning elements for transforming the resistance coupled to the first node into a plurality of impedances at a second node, wherein the second node is configured to be coupled to an RF power source; and a test unit controller coupled to the adjustable tuning elements, wherein the test unit controller controls adjustment of the adjustable tuning elements for selected ones of the plurality of impedances at the second node.

Embodiments of the disclosure include a system for analyzing, qualifying or testing a radio frequency (RF) components, comprising: a radio frequency (RF) power source comprising an RF generator; and an impedance matching network having an output and input coupled to an output of the RF generator; a wideband RF variable impedance test load comprising: a variable impedance network comprising: a first node that is adapted for coupling to a resistance; and adjustable tuning elements for transforming the resistance coupled to the first node into a plurality of impedances at a second node, wherein the second node is configured to be coupled to the output of the impedance matching networking; and a test unit controller coupled to the adjustable tuning elements, wherein the test unit controller controls adjustment of the adjustable tuning elements for selected ones of the plurality of impedances at the second node.

Embodiments of the disclosure include a method of analyzing, qualifying or testing radio frequency (RF) components, comprising: delivering, by use of an RF generator, a first RF signal through an impedance matching network to a first node of the variable impedance network. The variable impedance network comprises: a controller; a second node that is adapted for coupling to a resistance element; adjustable tuning elements for transforming the resistance of the resistance element coupled to the second node into a plurality of load impedances at the first node; and an RF voltage sensor, an RF current sensor, and a frequency detector that are each coupled between the first node and the adjustable tuning elements. Then by matching, by use of the impedance matching network, a first impedance of the RF generator to one of the plurality of load impedances created at the first node of the variable impedance network, wherein the one of the plurality of load impedances is created by adjusting one or more of the adjustable tuning elements; and qualifying the impedance matching network or RF voltage sensor if a signal from the RF voltage sensor, the RF current sensor or the frequency sensor are within a range set relative to at least one of RF voltage sensor data, RF current sensor data and frequency detector data stored in memory, while the first impedance of the RF generator is matched to the one of the plurality of load impedances.

Embodiments of the disclosure include a method of analyzing, qualifying or testing radio frequency (RF) components, comprising: delivering, by use of an RF generator, a first RF signal through an impedance matching network to a first node of the variable impedance network, wherein the variable impedance network comprises: a controller; a second node that is adapted for coupling to a resistance element; adjustable tuning elements for transforming the resistance of the resistance element coupled to the second node into a plurality of load impedances at the first node; and an RF voltage sensor, an RF current sensor, and a frequency detector that are each coupled between the first node and the adjustable tuning elements; matching, by use of the impedance matching network, a first impedance of the RF generator to a first impedance of the plurality of load impedances created at the first node of the variable impedance network, wherein the first impedance of the plurality of load impedances is created by adjusting one or more of the adjustable tuning elements; and qualifying the impedance matching network or RF voltage sensor if a signal from the RF voltage sensor, the RF current sensor or the frequency sensor are within a range set relative to at least one of RF voltage sensor data, RF current sensor data and frequency detector data stored in memory, while the first impedance of the RF generator is matched to the first impedance of the plurality of load impedances. The method may also further comprise delivering, by use of an RF generator, a second RF signal through an impedance matching network to the first node of the variable impedance network; matching, by use of the impedance matching network, a second impedance of the RF generator to a second impedance of the plurality of load impedances created at the first node of the variable impedance network, wherein the second impedance of the plurality of load impedances is created by adjusting the one or more of the adjustable tuning elements; and wherein the qualifying the impedance matching network or RF voltage sensor further comprises qualifying the impedance matching network or RF voltage sensor if a signal from the RF voltage sensor, the RF current sensor or the frequency sensor is within a range set relative to at least one of RF voltage sensor data, RF current sensor data and frequency detector data stored in memory while the first impedance of the RF generator is matched to the first impedance of the plurality of load impedances and the second impedance of the RF generator is matched to the second impedance of the plurality of load impedances.

### BRIEF DESCRIPTION OF THE DRAWINGS

So that the manner in which the above recited features of the present disclosure can be better understood in detail, a more particular description of the disclosure, briefly summarized herein, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a schematic block diagram of a wideband variable impedance test load coupled to an RF generator and impedance matching network, according to specific example embodiments of this disclosure;

FIGS. 2A and 2B are schematic diagrams of RF impedance matching circuits, according to specific example embodiments of this disclosure;

FIG. 3 illustrates a schematic block diagram of a test unit controller, according to specific example embodiments of this disclosure;

FIG. 4 illustrates a schematic block diagram of an ECAT controlled variable impedance load coupled to an RF generator and impedance matching network under test, according to specific example embodiments of this disclosure;

FIGS. 5A and 5B illustrate a flow chart of a method for running a multipoint match qualification of an impedance matching network, according to specific example embodiments of this disclosure;

FIG. 6 illustrates a schematic block diagram of a system that may be adapted for sensor qualification and calibration using a wideband variable impedance load, according to specific example embodiments of this disclosure;

FIGS. 7A and 7B illustrate a flow chart of a method for sensor qualification and calibration using a wideband variable impedance load, according to specific example embodiments of this disclosure; and

FIGS. 8A and 8B are schematic block diagrams of forward and reverse RF transmission configurations, respectively, for match tuning and filter performance qualifications, according to specific example embodiments of this disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to apparatus and methods for testing and verification of equipment used in the manufacture of semiconductor devices. More specifically, embodiments provided herein generally include apparatus and methods for testing and verifying operation of radio frequency (RF) power generation and impedance matching equipment used for generating a plasma in a plasma chamber during semiconductor processing therein.

Embodiments for a wideband variable impedance load for high volume manufacturing qualifications and diagnostics of a radio frequency (RF) power source and impedance matching network are disclosed herein. The wideband variable impedance load may comprise a fixed value resistor operable at a plurality of frequencies and coupled with a variable impedance network capable of transforming the fixed value resistor into a plurality of complex impedances over a wide range of frequencies, e.g., from about 100 kHz to about 250 Mhz. The variable impedance network may comprise various adjustable and/or switched fixed value elements, e.g., variable value capacitors and switched fixed value inductors and capacitors to cover such a wide range of frequencies and impedances.

As used herein a “plurality of impedances” and a “plurality of frequencies” may be interpreted to be in context different impedances at different frequencies, different impedances at the same frequency, or different frequencies at the same impedance. The term “wideband” may be interpreted to mean over a wide range of different frequencies, and “wide range” may be interpreted to mean over a large number of different values. The terms “recording” and “storing in a memory” e.g., data, may be used interchangeably herein.

An adjustable wideband complex impedance load is disclosed that may be used in high-volume qualification testing of high-power RF generators and impedance matching networks, for example but not limited to, for plasma processing chambers. The adjustable wideband complex impedance load is capable of being set to a plurality of different complex impedances over a wide range of different frequencies. Change of impedance may be rapid, automatic and resettable from configuration settings stored in a memory and/or with a user interface. These configuration settings may be inductance and capacitance value settings of a variable impedance load in relation to desired complex impedances at test frequencies. This variable impedance load may be used for match and sensor qualifications in an automatic and/or manual test environment. Programs may be derived to run test, qualification and troubleshooting of RF generators and associated impedance matching networks at the factory during equipment testing, qualification and/or at vendor/customer manufacturing facilities during equipment testing and/or trouble shooting.

Built-in radio frequency (RF) voltage and current sensors measure RF voltage and RF current, and phase angle is determined therefrom as disclosed herein for determining load impedances as they change in real time during equipment testing, qualification and/or at vendor/customer manufacturing facilities during equipment testing and/or trouble shooting. Phase angle is determined by the lead or lag times between the RF voltage V(t) and RF current I(t) waveforms and is expressed in degrees θ. RF power P(t) is the product of voltage and current, or P(t)=V(t)*I(t), while the respective RMS (root-mean-square) values after sensor detection are P=V*I*cos θ, where θ is the phase angle between the voltage and current waveforms. Using Ohm's Law Z(t)=V(t)/I(t) or Z may be expressed as Z=R+jX, where R=Z cos θ and jX=Z sin θ. jX=jωL−j/ωC, where ω=2πf, f is in frequency, C is in farads and L is in henrys. R is resistance in ohms and jX is reactance in ohms, where +jX is inductive reactance and −jX is capacitive reactance. Power is frequency independent and impedance is frequency dependent.

Embodiments disclosed herein provide for the necessary equipment hardware, e.g., inductors, variable capacitance capacitors, a high-power RF dummy load (e.g., water cooled resistor) and RF sensors necessary for all match and sensor qualification requirements. Operation and control of the wideband complex impedance load disclosed herein may be adapted for remote, automated computer control such as, for example but is not limited to, Ethernet for Control Automation Technology (EtherCAT) or (ECAT) compliance and communications with user interfaces, e.g., laptop computer, and plasma chamber tools. A manual/fully automatic wideband complex impedance load may be adapted for use as a portable system for field testing and equipment debugging at any location.

Referring now to the drawings, the details of example embodiments are schematically illustrated. Like elements in the drawings will be represented by like numbers, and similar elements will be represented by like numbers with a different lower-case letter suffix.

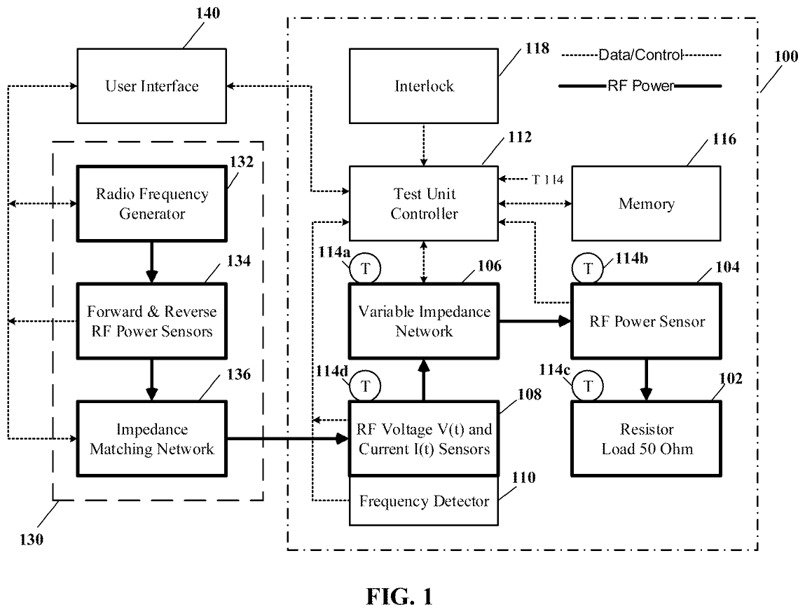

Referring to FIG. 1, depicted is a schematic block diagram of a wideband variable impedance test load coupled to an RF generator and impedance matching network, according to specific example embodiments of this disclosure. A wideband variable impedance test load 100 may comprise a fixed value resistor 102, an RF power sensor (wattmeter) 104, a variable impedance network 106, RF voltage and current sensors 108, a frequency detector 110, a test unit controller 112, temperature sensors 114, a memory 116 and an interlock circuit 118. The fixed value resistor 102 may be a water cooled non-inductive resistor for high power operation. The RF generator may be a high-power RF generator capable of generating kilowatts of RF power at one or more RF frequencies.

A radio frequency power source 130 may comprise a radio frequency generator 132, forward and reverse RF power sensors 134 and/or voltage and current sensors, and an impedance matching network 136. An output of the impedance matching network 136 may be coupled to an input of the variable impedance network 106 through the RF voltage and current sensors 108. Measurement of forward and reverse RF power with the forward and reverse RF power sensors 134 may be used to derive standing wave ratio (SWR). In some example embodiments described hereinafter, the radio frequency power source 130 may be a device under test (DUT).

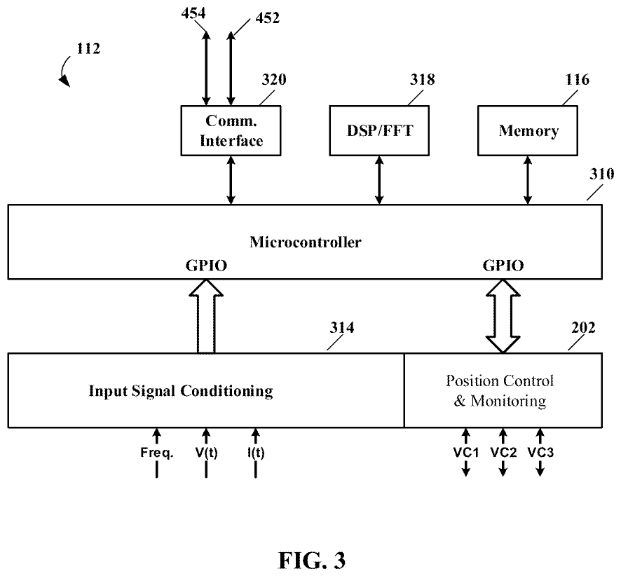

A user interface 140, e.g., computer (laptop), may communicate with the test unit controller 112 of the wideband variable impedance test load 100, and to the RF generator 132, the forward and reverse RF power sensors 134 and the impedance matching network 136. A more detailed description of the test unit controller 112 is shown in FIG. 3 and described in the specification hereinafter.

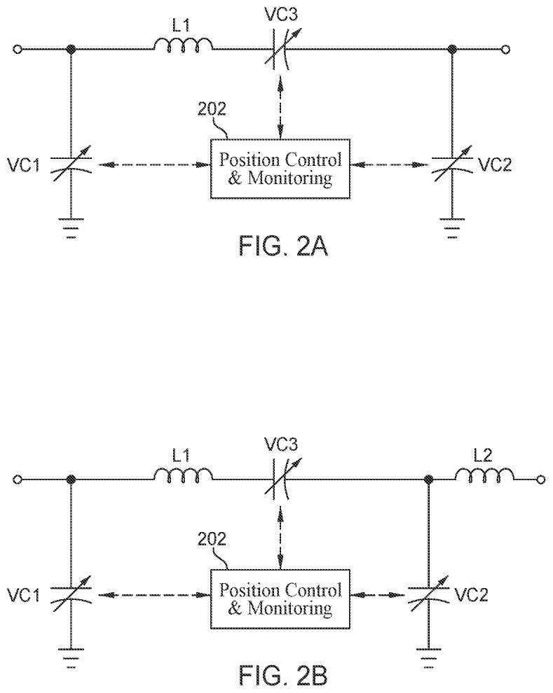

The test unit controller 112 may communicate with and control motorized variable capacitors (FIGS. 2A-2B) in the variable impedance network 106. The test unit controller 112 may also communicate with the RF voltage and current sensors 108, the frequency detector 110, the memory 116, the interlock circuit 118, and the temperature sensors 114. The test unit controller 112 may be used to communicate with the user interface 140 or other monitoring and control systems (not shown). Variable impedance load settings and automatic testing procedures may be stored in the memory 116 and may be executed by a processor within the test unit controller 112. Load impedance may be adjusted by the motorized vacuum variable capacitors (not shown) in the variable impedance network 106 and proper operation may be verified by the RF voltage and current sensors 108 at the input of the variable impedance load 100. Measurement readings from the RF voltage and current sensors 108 may be used to precisely control the variable load impedance at different target frequencies. In order to keep stable and consistent complex load values, temperature may be monitored in real time at multiple locations in the variable impedance load 100 with the temperature sensors 114. The interlock circuit 118 may also be implemented for safety purposes to control over temperature switches (not shown), cable-in-place switches (not shown), and match-in-place switches (not shown). In addition, for example but not limited to, a water cooled 50-ohm resistor 102 may be used as a fixed resistive load for high RF power operation and may be coupled to the output side of the variable impedance network 106 via the RF power sensor 104 (wattmeter).

Referring to FIGS. 2A and 2B, depicted are schematic diagrams of RF impedance matching circuits, according to specific example embodiments of this disclosure. In FIGS. 2A and 2B, three variable capacitors VC1, VC2 and VC3, e.g., motorized vacuum variable capacitors are shown. They may have a capacitive range, but are not limited to, from about 3 pF to about 5000 pF. L1 is an inductor and may have an inductive range of, but is not limited to, about 0.01 μH to about 1000 μH. VC3 may be used to adjust a target frequency from about 100 kHz to about 250 MHz, and VC1 and VC2 may be used to tune to a target impedance. In some embodiments, especially complex loads for lower frequencies, the RF circuit schematic configuration shown in FIG. 2B may be implemented. An additional inductor L2 may be added before the 50-ohm resistor load 102 for adjusting the variable impedance network 106 to a desired value. Inductor L2 may be in a range of, but is not limited to, about 0.01 μH to about 1000 μH. A low pass Pi matching circuit is shown in FIGS. 2A and 2B. In some embodiments, the RF matching circuit may be an L type circuit with two motorized vacuum variable capacitors, e.g., VC1 and VC3 only. The capacitance and/or inductance values of the variable elements, e.g., VC1, VC2, VC3; may be controlled and monitored by a position control and monitoring circuit 202 for each variable element (one shown). Additional capacitors and/or inductors may also be switched into the matching circuit as required (not shown). A motor position actuator of the position control and monitoring circuit 202 may also include a position sensor that indicates the mechanical position of the adjustable element, e.g., amount of shaft rotation of the variable vacuum capacitor or a synchronized stepper motor position count after minimum and maximum rotation positions have been determined (detection of maximum and minimum clockwise and counter-clockwise shaft rotations). Position values may be correlated in a capacitance (or inductance)—position value table so that capacitance and/or inductance values may be monitored and set to a desired position based upon a required capacitance/inductance value. Element position values may be used for monitoring, presetting and testing according to the teachings of this disclosure.

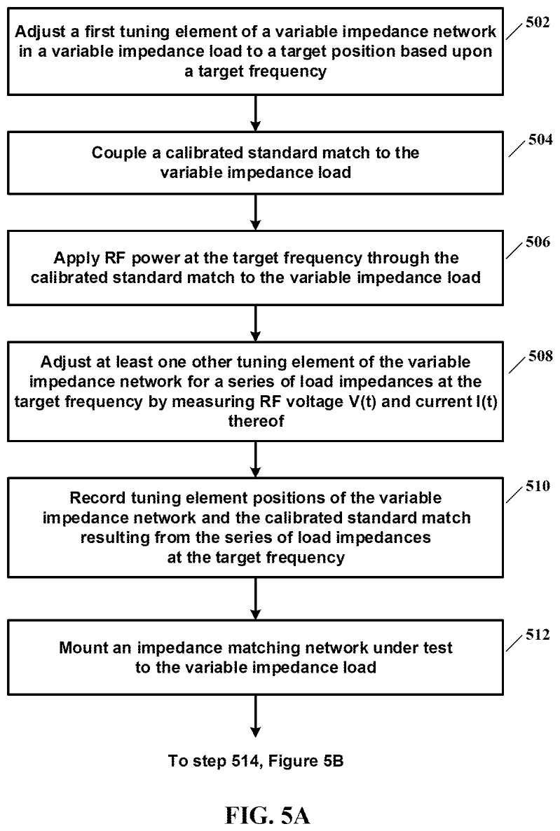

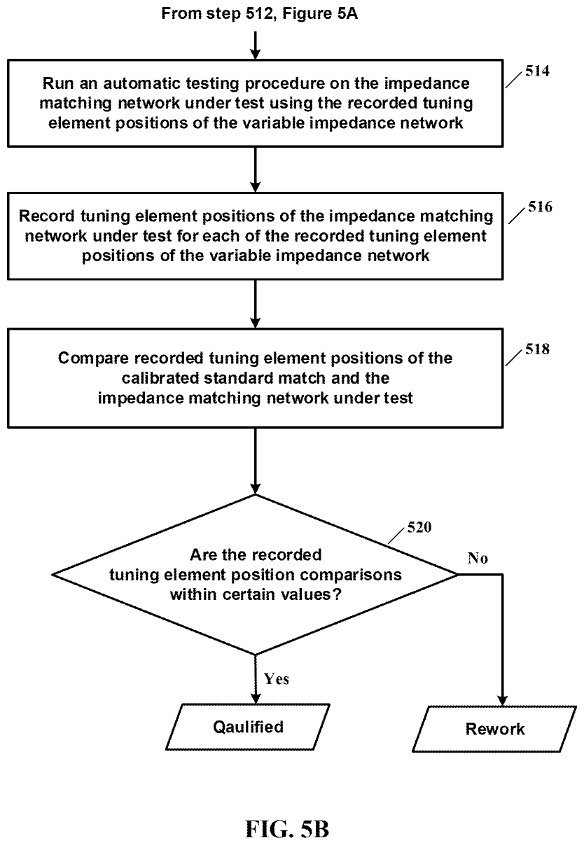

Referring to FIG. 3, depicted is a schematic block diagram of a test unit controller, according to specific example embodiments of this disclosure. The test unit controller 112 may monitor and control the variable impedance load 100 circuit elements. The test unit controller 112 may comprise a microcontroller 310, a memory (volatile and/or non-volatile) 116, a communications interface 320, input signal conditioning 314, and stepper motor drivers and position sensors 202. In addition, the microcontroller 310 may have a digital signal processing (DSP) and fast Fourier transform (FFT) capabilities in either an internal core processor or an external DSP/FFT processor 318. The microcontroller 310 may provide general purpose inputs and outputs (GPIO) for coupling to the input signal conditioning 314, voltage V(t), current I(t) and frequency (f), and the stepper motor drivers and position sensors 202. The voltage V(t) and current I(t) and frequency (f) data from the RF voltage and current sensors 108, and the frequency detector 110 may be input in real time to the microcontroller 310. The microcontroller 310 may then determine phase, and with frequency, determine the impedance at the input of the variable impedance network 106. The microcontroller 310 may also be in communications via the communications interface 320. The communications interface 320 may be adapted for communicating with protocols such as, for example but is not limited to, Ethernet for Control Automation Technology (EtherCAT) or (ECAT) compliance and serial RS-232, Ethernet, WiFi and Bluetooth communications with user interfaces, e.g., laptop computer, and plasma chamber tools. Software instructions (program) and data may be coded and stored within the memory 116 for processing by the external DSP/FFT processor 318. A software program (or computer instructions) readable by the processor in the test unit controller 112 determines which tasks may be performable by the components in the variable impedance load 100. Typically, the program, which is readable by the processor (e.g., microcontroller 310) in the variable impedance load 100, includes code, which, when executed by the processor, performs tasks relating to the testing scenarios described herein. The program may include instructions that may be used to control the various hardware and electrical components within the variable impedance load 100 to perform the various process tasks and various process sequences used to implement the methods described herein. In one embodiment, the program includes instructions that may be used to perform one or more of the operations described below in relation to FIGS. 5A, 7A and 8A.

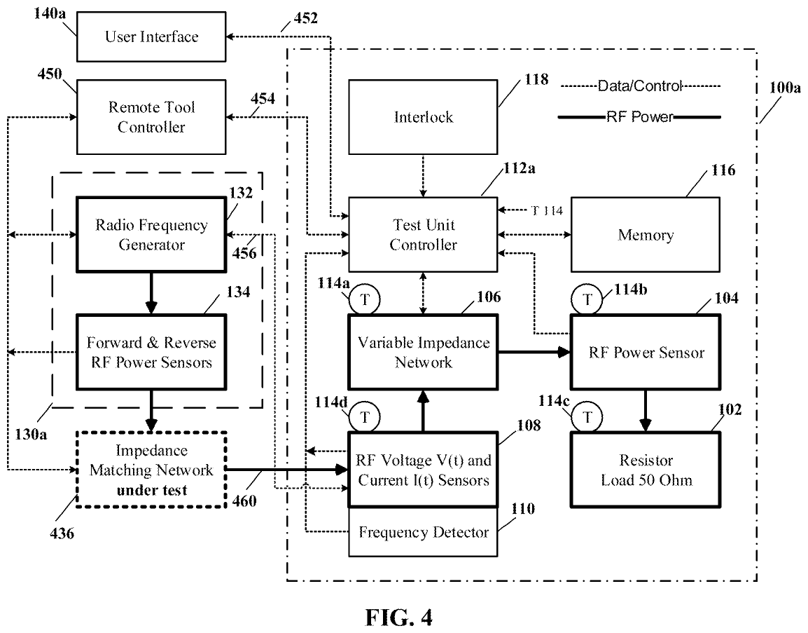

Referring to FIG. 4, depicted is a schematic block diagram of an ECAT controlled variable impedance load coupled to an RF generator and impedance matching network under test, according to specific example embodiments of this disclosure. According to the circuit shown in FIG. 4, the variable impedance load 100a may have three motorized vacuum variable capacitors in the RF circuit (see FIGS. 2A-2B and 3) of the variable impedance network 106; RF voltage and current sensors 108, a frequency detector 110 at the input of the variable impedance network 106, an interlock circuit 118, a local memory 116, multiple temperature sensors 114 and a 50-ohm resistor load 102, e.g., a water cooled non-inductive resistor for high power dissipation. All of these internal devices may be controlled by a local controller, e.g., test unit controller 112a, for example but not limited to, communicating using Ethernet for Control Automation Technology (EtherCAT) over a communication line 454. EtherCAT is a real time industrial Ethernet protocol. Due to short cycle time and low jitter, EtherCAT has benefits of high speed and accurate synchronization. The test unit controller 112a may serve as a local EtherCAT master. All match components, e.g., RF voltage and current sensors 108 and frequency detector 110, variable impedance network 106, capacitor control 202 (FIG. 2A), may be EtherCAT slave devices, which may be controlled by the test unit controller 112a. During qualification tests, a new matching network 436 under test may be coupled between an RF generator 132 and the variable impedance load 100a through a 50-ohm transmission line 460. The RF generator 132 may supply RF power at frequencies from about 100 kHz to about 250 MHz. A synchronization signal 456, e.g., transistor-transistor logic (TTL), may be provided to the RF voltage and current sensors 108 at the input of the variable impedance load 100a directly from the RF generator 132 or remote tool controller 450 for advanced pulse testing and debugging.

### Plasma Chamber Process Simulation

Impedance, frequency and power associated with a plasma chamber process may be measured with RF voltage, RF current, RF frequency and RF power sensors, and the values therefrom may be recorded during a representative plasma chamber process using a qualified radio frequency power source and operational plasma chamber doing a demonstrative plasma process. The recorded RF voltage, RF current, RF frequency and RF power readings may then be used to create a test program for simulation of the representative plasma chamber process by controlling operation of the wideband variable impedance test load 100 in combination with an RF power source 130 under test. The operating parameters of a known good and properly operational radio frequency power source may also be recorded for comparison with subsequently measured parameters of another radio frequency power source 130 under test. A library of different plasma chamber process simulations may be created for testing of RF power sources and/or impedance matching networks under many different operating requirements and conditions. The library of different chamber process simulations and related data may be used to train one or more artificial intelligence (AI) or machine learning (ML) software application running in the test unit controller that may be able to diagnose issues with a component under test and/or help determine that the component under test is able to function within an acceptable range of performance.

When a radio frequency power source 130 to be tested is coupled to the wideband variable impedance test load 100 running the process simulation test programs, the wideband variable impedance test load 100 will simulate (appear to be) a plasma chamber by replicating the recorded plasma process parameters. All operational parameters of the RF power source 130 under test may be measured and stored during the simulated plasma process. For example, operation of the RF generator 132, RF power sensors 134 and impedance matching network 136 comprising the RF power source 130 under test may be monitored and recorded for proper operation thereof. The readings from the RF voltage and current sensors 108, RF frequency detector 110 and RF power 104 sensor may further be used for test verification purposes of the RF power source 130 under test. The readings from the RF voltage and current sensors 108, RF frequency detector 110 and RF power 104 sensor may be stored as RF voltage sensor data, RF current sensor data, frequency detector data and RF power data in memory 116. The measured and stored readings and/or operational parameters may then be compared to operational parameters from a qualified (known good) RF power source previously recorded, and a determination made of the calibration and operability of the radio frequency power source 130 under test based upon the process simulation test results.

The variable impedance matching network 106 may be adapted to transform the 50-ohm resistor 102 to the required simulated (measured) chamber impedance. Capacitance/inductance values may be calculated to make this impedance transformation. For example, once the capacitance values required for impedance transformation are determined then the variable capacitors (VC1, VC2, VC3) may be positionally set to obtain those capacitance values, for example but not limited to, with a position/capacitance lookup table.

### Qualification Test Procedures

Referring to FIG. 4, a remote tool controller 450 may be provided for communicating with the impedance matching network 436 under test, RF generator 132 and the test unit controller 112a. The test unit controller 112a may communicate with the remote tool controller 450 using EtherCAT protocol on data communications line 454. The test unit controller 112a of the variable impedance load 100a may do a master to slave conversion which allows communication to the remote tool controller 450 acting as master on the EtherCAT data communications line 454. The test unit controller 112a may receive requests from the remote tool controller 450 and provide feedback thereto. Also, the remote tool controller 450 may receive forward and reflected power information from the RF power sensors 134 and thereby obtain data from the impedance matching network 436 under test. A cooperative intelligent qualification testing procedure may be achieved using the circuit configurations depicted and described herein. In addition, the user interface 140a and variable impedance load 100a (via test unit controller 112a) may feature serial control ports coupled via communications line 452 for uploading multipoint qualification procedures and complex load tuning algorithms by using an external software and application programming interface (API). The uploaded load tuning algorithms may include testing sequence recipes that may be used to simulate variations in the complex load during plasma ignition, variations in the complex load found during common processing plasma process sequences and other useful plasma processing simulations. Complex load impedances and variable capacitor motor positions may be monitored and accessed from external user interfaces 140a, e.g., laptop computers, which provides great flexibility in application and use of the variable impedance load 100a. Also, advanced complex load control and/or testing procedures may be deployed in real time. The variable impedance load 100a may operate fully autonomously, cooperatively with the remote tool controller 450 or manually controlled by the user interface 140a, e.g., computer laptop.

The wideband variable impedance test load 100a may be configured to provide a testing environment that may test over wide frequency/impedance ranges and may be used for RF power source 130 testing and debugging. The wideband variable impedance test load 100a may be fully and automatically controlled by the remote tool controller 450 and be tuned to different selected load impedances, for example but not limited to plasma chamber testing. The wideband variable impedance test load 100a may also be used for new RF power match equipment qualification in high volume manufacturing.

Real time readings at certain time intervals of the devices under test (DUT), e.g., RF voltage and current sensors 608 and real time phase derived therefrom, and tuning element positions of the impedance matching network 436 may be recorded along with a “time stamp” for each reading recorded. Temperature measurements from temperature sensors 114 may also be recorded and time stamped during a qualification test, along with RF generator power outputs correlated with DUT temperatures. From the recorded RF voltage, current, phase and time stamps thereof, impedance traces may be derived. An “impedance trace” is defined herein as a change in impedance over a time period. Tuning element position changes over a time period may be referred to as “tuning element position traces.” Similarly RF voltage, current, phase, and power traces may be defined from the measured/calculated and stored values thereof correlated with the associate time stamps.

These derived traces may be used for dynamic qualification testing of the DUT. For example, dynamic qualification testing may be used to simulate impedance transition states such as the response time of an impedance matching network to an impedance change (from variable impedance network 106) by characterizing the time required for tuning element positions of the impedance matching network 436 to change to a new value to match the impedance change. Temperature rise over time (temperature trace) resulting from RF power supplied to the impedance matching network 436 may also be used to compensate for variation in temperature of the one or more affected components over time that are under test and thus in determining qualification of a DUT. Swept frequencies (varies from low to high frequencies) of RF power from a test RF generator may be used for testing RF filters. A variable frequency RF generator may be used for testing impedance matching networks over both impedance and frequencies ranges (traces).

Referring to FIGS. 5A and 5B, depicted is a flow chart of a method for running a multipoint match qualification of an impedance matching network, according to specific example embodiments of this disclosure. This flow chart represents an example for running an automatic multipoint match qualification of an impedance matching network 436 (FIG. 4) under test. In step 502, a first tuning element, e.g., variable capacitor VC3, of the variable impedance network 106 may be adjusted to a target position (e.g., capacitance setting) based upon a target frequency. The target position(s) or settings may be determined empirically or from a preprogrammed test menu, and may be selected to simulate an impedance of a wideband variable impedance load found during a typical processing recipe that the impedance matching network will experience during operation, such as a step within a plasma processing recipe. In step 504, a calibrated standard (qualified) match may be coupled to the variable impedance load 100a. In step 506, RF power at a target frequency may be applied through the calibrated standard match to the input node of the variable impedance load 106 that may be coupled to the transmission line 460.

In step 508, tuning elements of the variable impedance network 106 may be adjusted for desired test load impedances as calculated from the RF voltage and current measured by the RF voltage and current sensors 108. The frequency would be known from the frequency setting of the RF generator 132 or may be measured by the frequency detector 110. In step 510, the tuning element positions of the variable impedance network 106 and the calibrated standard (qualified) match for each of the test load impedances at the target frequencies may be recorded (stored in memory 116). Optionally, recording a plurality of tuning element positions (position traces) of the calibrated standard (qualified) match during position transitions may be time stamped for creating and comparing response times thereof. These test load impedances may then be used as testing points for the qualification of other unqualified impedance matching networks 436 that are under test. As is discussed further below, the stored test load impedances may include data relating to the various component settings and impedances traces over time as a way to determine if the matching networks 436 is functioning correctly and/or predict any possible future device component failures. The stored information may be stored in memory as a lookup table or a real-time map measured using a network analyzer. The stored information may include RF voltage data, RF current data and/or frequency data, which was previously collected by the RF voltage and current sensors 108 and frequency detector 110 and stored in memory. In step 512, an impedance matching network 436 under test is mounted to and in RF communications with the variable impedance load 100a (variable impedance network 106). In step 514, an automatic testing procedure may be performed on the impedance matching network under test using the recorded (stored) tuning element positions of the variable impedance network.

In step 516, the tuning element positions of the impedance matching network 436 under test (DUT) may be recorded for each of the test load impedances presented during testing. Optionally, recording a plurality of tuning element positions (position traces) of the match DUT during position transitions may be time stamped for creating and comparing the response times (position traces) of the match DUT to the position traces of the previously recorded calibrated standard (qualified) match. In step 518, the recorded tuning element positions of the impedance matching network 436 under test for each of the test load impedances may be compared to the recorded (stored) tuning element positions of the calibrated standard (qualified) match at those same test load impedances. The position traces for of both the match DUT and qualified match may be compared for dynamic position qualification of the match DUT. In step 520, if the comparisons between the tuning element positions, and optionally dynamic position transition times, of the qualified match 638 and the impedance matching network 436 under test are within certain acceptable values, then the impedance matching network 436 under test may be deemed “qualified.” If not, then the impedance matching network 436 is not qualified and must be repaired and/or recalibrated (reworked). Similar testing may be used to verify tuning element match ranges and synchronizations of the adjustable tuning element positions with expected capacitance/inductance values.

### Sensor Calibration

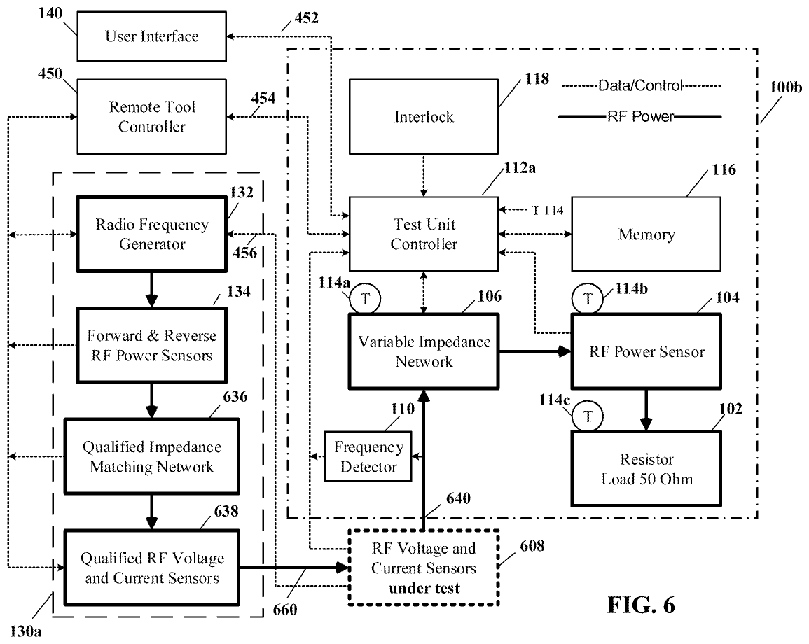

Referring to FIG. 6, depicted is a schematic block diagram of a system that may be adapted for sensor qualification and calibration using a wideband variable impedance load, according to specific example embodiments of this disclosure. A qualified impedance matching network 636 e.g., one having calibrated and qualified matching element settings, and calibrated and qualified RF voltage and current sensors 638 may be coupled between an RF generator 132 and a variable impedance load 100b. The RF voltage and current sensors 608 under test may be mounted at an input 640 of the variable impedance load 100b and be calibrated and certified by comparing readings of the RF voltage and current sensors 608 under test with the readings of the qualified and calibrated RF voltage and current sensors 638 at various complex impedance settings of the variable impedance network 106.

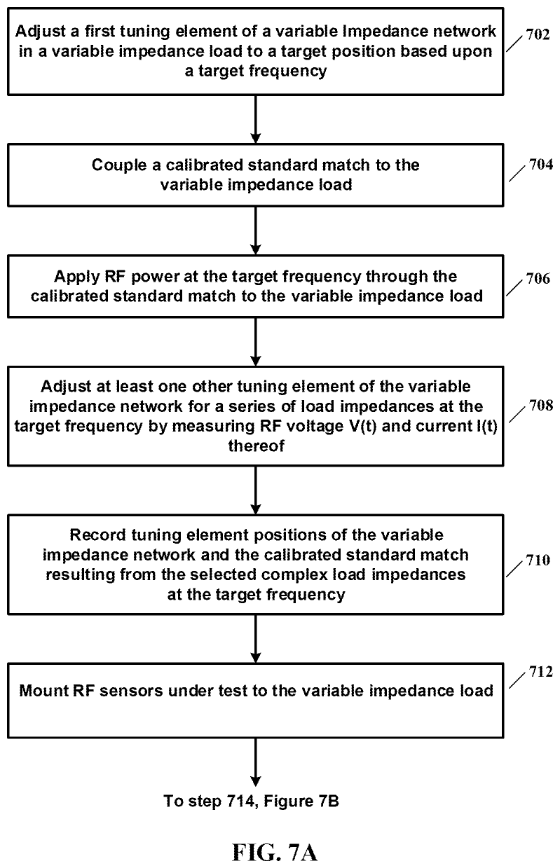

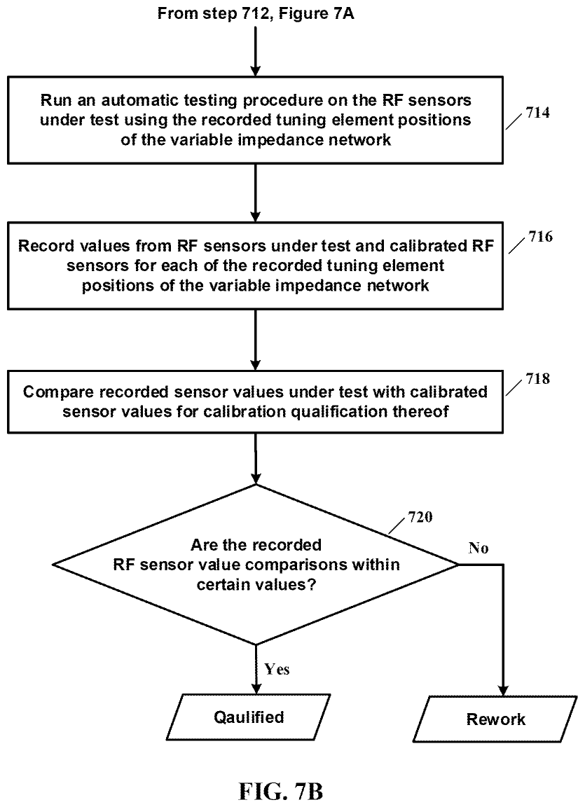

Referring to FIGS. 7A and 7B, depicted is a flow chart of a method for sensor qualification and calibration using a wideband variable impedance load, according to specific example embodiments of this disclosure. This flow chart represents an example for running an automatic multipoint sensor qualification and calibration using the equipment configuration shown in FIG. 6. In step 702, a first tuning element, e.g., variable capacitor VC3, of the variable impedance network 106 may be adjusted to a target position (e.g., capacitance setting) based upon a target frequency. The target position(s) or settings may be determined empirically or from a preprogrammed test menu. In step 704, a calibrated standard (qualified) match may be coupled to the variable impedance load 100a. In step 706, RF power at a target frequency may be applied through the calibrated standard match to the input node of the variable impedance load 106 that may be coupled to the transmission line 660.

In step 708, tuning elements of the variable impedance network 106 may be adjusted for desired test load impedances as calculated from the RF voltage and current measured by the qualified RF voltage and current sensors 638. The frequency would be known from the frequency setting of the RF generator 132 or may be measured by the frequency detector 110. In step 710, the tuning element positions of the variable impedance network 106 for each of the test load impedances at the target frequencies may be recorded (stored in memory 116). Optionally, recording a plurality of tuning element positions (position traces) of the variable impedance network 106 during position transitions may be time stamped for creating and comparing response times thereof. These test load impedances may then be used as testing points for the calibration and qualification of RF voltage and current sensors 608 under test. In step 712, RF voltage and current sensors 608 under test may be mounted to and in RF communications with the variable impedance load 100b (variable impedance network 106). In step 714, an automatic testing procedure may be performed on RF voltage and current sensors 608 under test using the recorded (stored) tuning element positions of the variable impedance network.

In step 716, the information from the RF sensors 608 under test and the qualified RF voltage and current sensors 638 may be recorded for each of the test load impedances presented during testing (recorded tuning element positions). Optionally, recording a plurality of sensor readings (current and voltage) of the RF sensors under test during position transitions of the tuning elements that may be time stamped for subsequent voltage and current traces of the RF sensors under test. In step 718, the information from RF voltage and current sensors 608 under test may be compared with the RF voltage data and RF current data collected from qualified (calibrated) RF voltage and current sensors 638. Optionally, comparison of the dynamic voltage and current traces of the RF voltage and current sensors 608 under test and the qualified (calibrated) RF voltage and current sensors 638 may be determined. In step 720, if the recorded sensor value comparisons between the qualified (calibrated) RF voltage and current sensors 638 and the RF voltage and current sensors 608 under test are within certain acceptable values, and optionally RF voltage and current trace times, then the RF voltage and current sensors 608 under test are deemed calibrated or “qualified.” If not, then the RF voltage and current sensors 608 under test are not qualified and must be repaired and/or recalibrated (reworked).

### Match Tuning and Filter Performance Qualifications

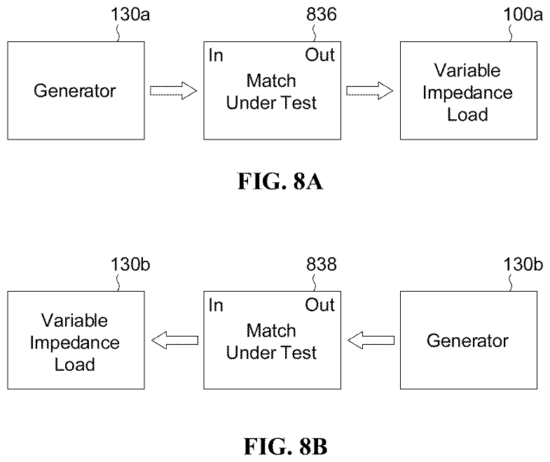

Referring to FIGS. 8A and 8B, depicted are schematic block diagrams for forward and reverse RF transmission configurations, respectively, for match tuning and filter performance qualifications, according to specific example embodiments of this disclosure. FIG. 8A shows a forward RF power test setup that may be used to verify tuning positions of impedance matching networks under test. In the forward RF power test setup, an RF generator 130a, may be set to a match target frequency, connected to an input of an impedance matching network 836 under test, and a variable impedance load 100a may be connected to an output thereof through 50-ohm coaxial transmission lines. The testing process may be completed using the forward RF power test setup illustrated in FIG. 8A and may be similar to the method illustrated in FIG. 5A, and discussed above.

FIG. 8B shows a reverse RF power test setup that may be used to check RF filter performance. In the reverse RF power test setup, an RF generator 130b not at the match target frequency may be connected to an output of an impedance matching network 838 under test and a variable impedance load 100b may be connected to an input thereof through 50-ohm transmission lines. Built-in RF sensors (not shown) at the input of the variable impedance load 100b may measure power reaching the variable impedance load 100b and other parameters to verify RF filter performance. The RF generator frequency in the reverse RF power test setup of FIG. 8B may generally be determined based on available RF power frequencies and possible harmonic frequencies in a plasma processing chamber.

### Dynamic Qualification Test Procedures

Each of the aforementioned qualification test procedure steps may be performed using multiple settings of the tuning element positions of the variable impedance network over certain periods of time, e.g., real-time complex impedance control over time. Thus producing impedance traces, e.g., a series of a single-point impedance settings stored over a period of time. Such impedance traces, when measured in combination with a qualified impedance matching network and/or qualified RF voltage and current sensors, may be stored in a memory of a test unit controller and/or a tool controller. The stored impedance traces over time may then be used for dynamically testing and analysis of a device under test (DUT). Impedance traces may converted and/or stored in memory so that the tuning element positions of the variable impedance network over certain periods of time may be used to adjust portions of the testing process and/or determine how a DUT is performing. Therefore, the various dynamic parameters of a DUT may be evaluated by using the recorded impedance traces. The dynamic measurements may thus provide additional process qualification criteria to assure that the DUT is functioning as expected and as desired over a wider range of process settings.

In some embodiments, the test unit controller and/or a tool controller may be configured to run test sequences on the DUT autonomously. During these test sequences the test unit controller and/or tool controller may be configured to adjust, for example, the RF power level and frequency of the RF signal provided from the RF source, and adjust the impedances created by the variable impedance network by adjusting the settings of the tuning element positions over certain periods of time. The test unit controller and/or tool controller may also be configured to receive feedback from the RF voltage and current sensors 108, frequency detector 110 and/or a temperature sensor to improve the control of the impedance created by the variable impedance network during the testing of the DUT.

For example, but is not limited to, instantaneous and measured response times of the variable capacitors VC1, VC2 and VC3; and test repeatability of the settings for the variable capacitors VC1, VC2 and VC3 may be used to improve the DUT qualification process and/or determine how a DUT is performing. Temperature profiles of the impedance matching network taken over time and at various RF power levels may also be collected. Frequency sweeping by the RF generator may be used for testing of impedance matching networks, RF filters and RF sensors/detectors. Dynamic testing repeatability of an impedance matching network and/or RF voltage and current sensors may be determined.

Measured impedances values, impedance traces and/or tuning element positions of the variable impedance network over certain periods of time may be stored in the test unit controller and/or tool controller and be used to perform dynamic testing and qualification of DUTs. The measured impedance values, impedance traces and or tuning element positions information may be stored in memory, a lookup table, or a map measured using a network analyzer for analysis purposes. Varying RF power levels, RF frequencies and test load impedances (tuning element positions of the variable impedance network) over time, while monitoring RF sensor (voltage and current) readings, phase, frequency and temperature of DUTs then comparing the resulting measurements with the same measurements previously made from a qualified matching network and RF sensors stored in a memory may be used to determine whether the DUT meets desired qualification standards. The tool controller may run test sequences autonomously, including but not limited to, changing power level, frequency and load impedances. Feedback control of the variable impedance network, along with real-time temperature monitoring and compensation, may be used to improve the accuracy of the impedance set by the variable load impedance during testing and thus improve the DUT qualification process.

In one example of a dynamic qualification testing process, the test unit controller and/or tool controller may be used to measure and qualify the dynamic response of a DUT. Initially, during the dynamic qualification testing a plurality of position settings of at least one of the variable capacitors VC1, VC2 and VC3 of the variable impedance network may be stored in memory so that the variable capacitor settings may be used to test a series of selected complex load impedances during a future testing sequence. Next, a calibrated standard match may be connected to the output of an RF source and the input of the variable impedance network that may be connected to load resistor. Then RF power may be applied through the calibrated standard match, variable impedance network and load resistor, while the RF voltage and current sensors, frequency sensors and temperature sensors collect data as the complex impedance is varied in real time using the previously stored the variable capacitor settings. During the testing of the calibrated standard match, feedback may be provided by the sensors to allow the test unit controller and/or a tool controller to control the settings of the variable capacitors and/or RF generator frequency to form load impedance traces, while the variable capacitor positions, response time, RF voltage data, RF current data, frequency data is collected. The formed load impedance traces may then be stored in memory. Then the dynamic qualification testing process may be performed a plurality of times on a DUT using an automatic testing procedure that utilizes one or more stored impedance traces for qualification of the DUT.

Additionally, in some other embodiments, a dynamic qualification testing process may use prior formed impedance traces to qualify a DUT. The impedance trace data may be determined and/or predicted from data collected during prior test runs. Alternately, a user may define impedance traces by uploading prior collected data or by use of a user interface. Initially, during the dynamic qualification testing a plurality of position settings of at least one of the variable capacitors VC1, VC2 and VC3 of the variable impedance network may be stored in memory so that the variable capacitor settings may be used to test a series of selected complex load impedances during a future testing sequence. The created impedance trace may be stored in memory as a lookup table or a map measured using a network analyzer. Next, a DUT is connected to the output of an RF source and the input of the variable impedance network that is connected to a load resistor. Then the dynamic qualification testing process may be performed a plurality of times on the DUT using an automatic testing procedure that utilizes one or more of the stored impedance traces. During the testing of the DUT, feedback may be provided by the sensors to allow the test unit controller and/or a tool controller to control the settings of the variable capacitors and/or RF generator frequency to form DUT impedance traces, while the variable capacitor positions, response time, RF voltage data, RF current data, frequency data and/or temperature data is collected in real time. The formed DUT impedance traces may then be stored in memory. The collected data, which includes the DUT impedance traces, may then be compared with stored qualification data to determine if the DUT has met a desired set of criteria.

The present disclosure has been described in terms of one or more embodiments, and it should be appreciated that many equivalents, alternatives, variations, and modifications, aside from those expressly stated, are possible and within the scope of the disclosure.

What is claimed is:

1. A system for analyzing, qualifying or testing radio frequency (RF) components, comprising:
a variable impedance network comprising:
a first node that is adapted for coupling to a first resistance element; and
adjustable tuning elements for transforming the resistance coupled to the first node into a plurality of impedances at a second node,
wherein the second node is configured to be coupled to an RF power source; and
a test unit controller coupled to the adjustable tuning elements, wherein the test unit controller controls adjustment of the adjustable tuning elements for selected ones of the plurality of impedances at the second node.

2. The system of claim 1, further comprising the first resistance element, and first resistance element is a fixed value resistor coupled to the first node of the variable impedance network, wherein the resistance of the fixed value resistor is 50 ohms.

3. The system of claim 1, wherein the variable impedance network is adapted to receive an RF signal from the RF power source that has a frequency within a range of from about 100 kHz to about 250 MHz.

4. The system of claim 1, further comprising an RF power sensor coupled between the first node of the variable impedance network and the resistance.

5. The system of claim 1, further comprising a plurality of RF sensors and a frequency detector coupled to the second node of the variable impedance network.

6. The system of claim 5, wherein the plurality of RF sensors are RF voltage and RF current sensors.

7. The system of claim 6, wherein the test unit controller comprises:
a microcontroller having
inputs coupled to the RF voltage and RF current sensors, and the frequency detector,
inputs and outputs for monitoring positions of and controlling the adjustable elements of the variable impedance network, and
a memory that includes information relating to a plurality of settings of one or more of the adjustable tuning elements stored therein;
wherein the plurality of settings of one or more of the adjustable tuning elements are configured to be used to create the plurality of impedances at the second node.

8. The system of claim 1, wherein the RF power source comprises:
an RF generator; and
an impedance matching network having an input coupled to an output of the RF generator and an output adapted for coupling to the second node of the variable impedance network.

9. The system of claim 8, wherein the RF generator is a high-power RF generator.

10. A system for analyzing, qualifying or testing radio frequency (RF) components, comprising:
a radio frequency (RF) power source comprising
an RF generator; and
an impedance matching network having an output and input coupled to an output of the RF generator;
a wideband RF variable impedance test load comprising:
a variable impedance network comprising:
a first node that is adapted for coupling to a resistance; and
adjustable tuning elements for transforming the resistance coupled to the first node into a plurality of impedances at a second node,
wherein the second node is configured to be coupled to the output of the impedance matching networking; and
a test unit controller coupled to the adjustable tuning elements,
wherein the test unit controller controls adjustment of the adjustable tuning elements for selected ones of the plurality of impedances at the second node.

11. The system of claim 10, further comprising forward and reverse RF power sensors coupled between the output of the RF generator and the input of the impedance matching network.

12. The system of claim 10, further comprising a plurality of RF sensors and a frequency detector coupled between the second node of the variable impedance network and the output of the impedance matching network.

13. The system of claim 10, further comprising an RF power sensor coupled between the first node of the variable impedance network and the resistance.

14. The system of claim 10, wherein the test unit controller comprises:
a microcontroller having
inputs coupled to the RF voltage and RF current sensors, and the frequency detector,
inputs and outputs for monitoring positions of and controlling the adjustable elements of the variable impedance network,
a memory that includes information relating to a plurality of settings of one or more of the adjustable tuning elements stored therein, and
a communications interface;
wherein the plurality of settings of one or more of the adjustable tuning elements are configured to be used to create the plurality of impedances at the second node.

15. The system of claim 10, further comprising a user interface for controlling testing operations of the RF power source and the wideband RF variable impedance test load.

16. The system of claim 15, wherein a remote tool controller is in communication with the communications interface of the test unit controller.

17. A method of analyzing, qualifying or testing radio frequency (RF) components, comprising:
delivering, by use of an RF generator, a first RF signal through an impedance matching network to a first node of the variable impedance network, wherein the variable impedance network comprises:
a controller;
a second node that is adapted for coupling to a resistance element;
adjustable tuning elements for transforming the resistance of the resistance element coupled to the second node into a plurality of load impedances at the first node; and
an RF voltage sensor, an RF current sensor, and a frequency detector that are each coupled between the first node and the adjustable tuning elements;
matching, by use of the impedance matching network, a first impedance of the RF generator to a first impedance of the plurality of load impedances created at the first node of the variable impedance network, wherein the first impedance of the plurality of load impedances is created by adjusting one or more of the adjustable tuning elements; and
qualifying the impedance matching network or RF voltage sensor if a signal from the RF voltage sensor, the RF current sensor or the frequency sensor are within a range set relative to at least one of RF voltage sensor data, RF current sensor data and frequency detector data stored in memory, while the first impedance of the RF generator is matched to the first impedance of the plurality of load impedances.

18. The method of claim 17, further comprising:
delivering, by use of an RF generator, a second RF signal through an impedance matching network to the first node of the variable impedance network;
matching, by use of the impedance matching network, a second impedance of the RF generator to a second impedance of the plurality of load impedances created at the first node of the variable impedance network, wherein the second impedance of the plurality of load impedances is created by adjusting the one or more of the adjustable tuning elements; and
wherein the qualifying the impedance matching network or RF voltage sensor further comprises qualifying the impedance matching network or RF voltage sensor if a signal from the RF voltage sensor, the RF current sensor or the frequency sensor is within a range set relative to at least one of RF voltage sensor data, RF current sensor data and frequency detector data stored in memory while the first impedance of the RF generator is matched to the first impedance of the plurality of load impedances and the second impedance of the RF generator is matched to the second impedance of the plurality of load impedances.
